(19) United States
(12) Patent Application Publication
(10) Pub. No.: US 2002/0017700 A1
(43) Pub. Date: Feb. 14, 2002

(54) Multilayer capacitor, semiconductor device, and electrical circuit board

(75) Inventors: Toru Mori, Tokyo (JP); Akinobu Shibuya, Tokyo (JP); Shintaro Yamamichi, Tokyo (JP); Takao Yamazaki, Tokyo (JP); Yuzo Shimada, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 09/899,585

(22) Filed: Jul. 5, 2001

(30) Foreign Application Priority Data
Jul. 6, 2000 (JP) P2000-205675

(51) Int. Cl. H01L 23/48; H01L 23/52; H01L 29/40

(52) U.S. Cl. 257/532; 257/738

(57) ABSTRACT

The present invention provides a multilayer capacitor advantageously used as a decoupling capacitor having sufficient capacitance, low self inductance, and a high LC resonance frequency, and a semiconductor device and an electric circuit board that use the same. The electric circuit board of the present invention uses as a decoupling capacitor a three lead multilayer capacitor having a structure wherein a feed-through electrically connected to the power source line of an LSI is surrounded by two internal electrodes connected to a ground line via a dielectric layer. A multilayer capacitor can be used in which a plurality of holes 8, 9, and 10 are provided on a capacitor chip where the plurality of dielectric layers 7 and the plurality of electrode layers 11 and 12 are alternately multilayer, and dielectric parts are provided that electrically connect to a portion of the electrode layers on the internal surface of a portion of the holes among the plurality of holes.

### BACKGROUND OF THE INVENTION

1. Field of the Invention

The present invention relates to a multilayer capacitor, semiconductor device, and an electric circuit substrate, and in particular to a decoupling capacitor that is disposed in proximity to an LSI that operates at high speed, and compensates the voltage fall that occurs during a fluctuation in the load in the LSI.

2. Description of the Related Art

When a clock signal that changes rapidly is generated from an LSI, as shown in FIG. 11B, a drop in voltage A corresponding to the following equation 1 is generated due to the resistance R present in the wiring between the power source and the LSI, and the impedance L:

ΔV=R×Δi+L×di/dt (1)

Here, R denotes the resistance of the wiring and the capacitor, L denotes the impedance, ΔI denotes the current changing over time Δt.

Therefore, the larger R, L, and the load fluctuation di are, or the smaller the fluctuation time dt is, the voltage drop ΔV increases. In recent years, the clock frequency of the LSI has become high speed, exceeding several hundred MHz. This means that the time tr of the rise of the pulse waveform in a digital circuit is becoming equal t the fluctuation time of the load. The faster the clock frequency, the shorter the rise time tr, and thus the voltage drop AV becomes larger.

In order to make this voltage drop small, connecting capacitors in parallel is effective for LSI. These capacitors are generally called decoupling capacitors. While compensating a momentarily dropping voltage from the power source that occurs during a load change may not happen in time when the clock frequency of an LSI becomes fast, by disposing decoupling capacitors in proximity to the LSI and supplying a load from there, the voltage drop in the LSI can be compensated.

When the self inductance and internal resistance of the decoupling capacitors is assumed to be zero, the charge Q(=C×V) accumulated in the capacitor can be supplied to the LSI instantaneously during the load fluctuation, and the voltage fluctuation of the LSI can be made zero. However, actually because of the presence of self inductance in the capacitor, LC resonance occurs at a certain frequency, and at a frequency equal to or greater than this, the functioning as a capacitor is lost. Therefore, when the clock frequency of the LSI becomes high, at the same time the LC resonance frequency f of the coupling capacitor must become high. The LC resonance frequency f is represented by the following equation:

f²=1/(4×π×L×C) (2)

Therefore, a capacitor having a small C and a small L must be selected as a decoupling capacitor. As a decoupling capacitor, multilayer ceramic capacitors that have a small impedance at high frequencies and a capacitance of 0.1° F. or less have come to be widely used. A multilayer ceramic capacitor not only has a small ESR (equivalent serial resistance) compared to an electrolyte capacitor, but also has a small self inductance.

As shown, for example, in FIG. 10A, in the conventional multilayer capacitor, terminal electrodes 40 are formed at both ends of the chip. In addition, as shown in FIGS. 10B and 10C, a plurality of internal electrodes 42 are disposed in the dielectrics 41, and these internal electrodes 42 are alternately connected to the terminal electrodes 40 at both ends of the chip.

Conventionally, when taking as an example a multilayer capacitor widely used as a decoupling capacitor for compensating a voltage drop in an LSI, the capacity C=0.01 F and the self inductance L=0.4 nH. When the resonance frequency f of this capacitor is represented as (2πf)²×L×C=1, it is about 80 MHz.

In recent years, along with the increasing speeds, the current in an LSI has become large. Here, it is assumed that the LSI (A) has a switching frequency of 100 MHz, a maximum power consumption of 4A, and a power source voltage of 3.3 V, and LSI (B) has a switching frequency of 500 MHz, a maximum power consumption of 18A, and a power source of 1.8 V. In addition, we will calculate the capacitance necessary to compensate the voltage drop ΔV caused between clocks in the coupling capacitor. When the clock frequency is f, the rise time tr of the current can be assumed to be approximated by equation 3:

Tr=¼ f (3)

In order to compensate a voltage drop of the power source voltage, from the relationship ΔQ=C×ΔV=I×tr, the necessary capacitance C for LSI (A) is 4A×(0.35/(1×10⁸s))/(3.3 V×5%)=0.085 μF, and for LSI (B) is 18A×(0.35/(0.5×10⁹s))/(1.8 V×5%) =0.14 μF. This means that when the clock frequency of the LSI becomes fast and the power consumption becomes large, the necessary capacitance of the decoupling capacitors becomes large. However, in the case that the self inductance of the decoupling capacitors is the same and only the capacitance becomes large, in contrast, the LC resonance frequency f becomes low.

Therefore, in a capacitor used in a decoupling capacitor for load change compensation in an LSI, when using a capacitor having a self inductance that is even slightly smaller, the LC resonance frequency is made high, and thus it is more effective.

A feed-through capacitor such as a three lead capacitor is conventionally well known as a capacitor whose high frequency characteristics are superior to those of a normal multilayer ceramic capacitor. The normal multilayer ceramic capacitor, as shown in FIG. 10, provides capacitance at both ends of the rectangular body in the longitudinal direction, whereas in a three lead capacitor, as shown for example in FIG. 1, the resistance between both terminal electrodes I in the longitudinal direction is equal to or less than 0.1Ω, and differs on the point of providing capacitance between a terminal electrode 2, which is formed on the side surface perpendicular to the longitudinal direction, and a terminal electrode I in the longitudinal direction. The three lead capacitor is used conventionally to exclude power source noise by connecting the feed-through electrode to the power source line and the ground electrode to the ground.

In contrast, as disclosed in the “Nikkei Electronics”, Apr. 19, 1999, pp. 144 to 145, the self inductance becomes small as the dielectric becomes thinner. Thereafter, several inventions related to semiconductor devicees using thin film capacitors have been reported. Examples are Japanese Unexamined Patent Application, First Publication, No. Hei 11-45822 and Japanese Unexamined Patent Application, First Publication, No. Hei 8-97360.

However, there are no reports of examples of using a feed-through capacitor such as a three lead capacitor as a decoupling capacitor for compensating a momentary drop in the power source voltage that occurs during a load change in an LSI. The reason is that this type of decoupling capacitor is equal to or less than the LC resonance frequency of the multilayer ceramic capacitor having a normal clock frequency, that is to say, a two load multilayer ceramic capacitor, and thus the inexpensive two lead multilayer ceramic capacitor has been sufficiently suitable.

A thin film capacitor can obtain a sufficient capacitance and an LC resonance frequency higher than a normal multilayer ceramic capacitor, but mounting on a substrate has been somewhat difficult. In addition, because thin film processes have a high cost, a lower cost method of realization is required.

Furthermore, because an inductance component is present not just present in the capacitors but in the wiring between the decoupling capacitors and the LSI as well, it is desirable that this inductance be made a small as possible. As is generally well known, for 1 mm of wiring about 1 nH of self inductance is present. In contrast, the self inductance of the multilayer ceramic capacitor having the conventional structure described above has about 0.4 nH. Therefore, when mounting a multilayer ceramic capacitor 1 mm from the pad of the LSI, effectively an inductance of 1+0.4=1.4 nH is present. Strictly speaking, because wiring is present inside the LSI as well, there is self inductance present in this part as well, but for the present this will be ignored for the sake of convenience.

As the wiring between the LSI and the decoupling capacitor becomes longer, the self inductance of the wiring becomes a dominating factor, and thus a reduction of the self inductance due to a capacitor comes to be almost completely ignored. Therefore, the length of the wiring between an LSI pad and a decoupling capacitor must be equal to or less than a certain length.

### SUMMARY OF THE INVENTION

In consideration of the above-described problems, it is an object of the present invention to provide an advantageous multilayer capacitor having a sufficient capacitance, low self inductance, and a high LC resonance frequency for use in a decoupling capacitor for load change compensation in an LSI. In addition, it is an object of the present invention to provide a semiconductor device and an electric circuit board on which this is mounted that can be mounted easily on the board and further decreases the inductance between the decoupling capacitor and the LSI.

In order to attain the above-described objects, the multilayer capacitor of the present invention is characterized in providing holes that run through dielectric layers and electrode layers on a capacitor chip comprising alternating laminations of dielectric layers and electrode layers, and providing a first dielectric part electrically connected to a portion of the electrode layers among electrode layers on the inner surface of the holes of one portion among holes, and at the same time, provides a second dielectric part comprising a dielectrics electrically connected to the electrode layer adjacent to the electrode layer electrically connected to the first dielectric part among electrode layers on the inner surface of at least a portion of the holes among the remaining holes, and the main surface of the capacitor chip having hole openings exposed the dielectric layer.

Specifically, the multilayer capacitor of the present invention has as a basis a capacitor chip in which dielectric layers and electrode layers are alternately multilayer, which allows the formation of a thin film capacitor. In addition, holes that run through the capacitor chip are provided, and the first electrode that is electrically connected to a portion of the electrode layers among electrode layers on the inner surface of a portion of the holes among holes is provided, and a second inducting part electrically connected to the electrode layer adjacent to the electrode layer at the inner surface of the other holes is provided, and thereby this multilayer capacitor is equivalent to a three lead capacitor. Because a three lead capacitor has inherently low self inductance properties, a capacitor having sufficient capacitance, a low self inductance, and a high LC resonance frequency can be realized by the present invention.

In addition, the structure can provide a third dielectric part on the inner surface of the holes that remain after excluding the holes provided by the first dielectric part and the holes provided by the second dielectric part, wherein there is no electrical connection between this third dielectric part and electrode layers.

When structured in this manner, in the case that the multilayer capacitor of the present invention is integrated with a semiconductor device as will be described below, the third dielectric part can be connected to signal pads and the like in the semiconductor device.

In addition, a dielectric can be buried inside a hole provided in the first dielectric part, the second dielectric part, and the third dielectric part. Thereby, because dielectrics are buried in all of the holes, as will be explained below, in the case that the multilayer capacitor of the present invention is integrated with the semiconductor device, the terminal pads on the board side can be more reliably connected.

As a material for the dielectric layer, a compound having a perovskite structure or a hybrid of a compound having a perovskite structure and an organic material is preferably used.

Because a perovskite compound has a dielectric constant compared to other insulators, there is the advantageous point that the static capacitance of the capacitor per unit area can be made high. In addition, in the case that the capacitor is built into a resin build-up substrate, because the dielectric must be formed at a low temperature, it is necessary that an organic film be used as the dielectric layer. However, the dielectric constant of an organic film does not reach 10. Thus, by using an organic or inorganic hybrid material that is a product of reacting an organic film material monomer and the precursor of a perovskite compound, an organic film having a dielectric constant of about 30 to 50 can be obtained. This can be used as a dielectric layer.

The semiconductor device of the present invention is characterized in the multilayer capacitor of the present invention being fixed to the surface side on which terminal pads of the semiconductor device are provided, the power source pads among terminal pads and the first dielectric part being electrically connected, and the ground pad and the second dielectric part being electrically connected.

Among the capacitors of the present invention, in the case of a capacitor having a third dielectric part, the signal pad of the semiconductor device and the third dielectric part can be electrically connected.

In addition, the semiconductor device preferably is a type of semiconductor device having electrode pads, solder balls, pins, and the like disposed on one surface. Examples are bare chips and semiconductor packages such as a BGA (Ball Grid Array), a CSP (Chip Size Package), a QFP (Quad Flat Package), or a PGA (Pin Grid Array). Additionally, a relay member for adjusting the gaps between terminals can be provided on one surface of the semiconductor device.

Specifically, the semiconductor device of the present invention combines a semiconductor device such as a bare chip, a BGA, or a CSP semiconductor device. In addition, because the electric source pad and the first dielectric part are electrically connected, the electrode layers connected to the first dielectrics become power source electrode layers, and because the ground pad and the second dielectrics are electrically connected, the electrode layers connected to the second dielectric part become ground electrode layers. In order to compensate the voltage drop that occurs during a change in the load in the semiconductor device, usually a decoupling capacitor must be disposed in proximity to the semiconductor device. On this point, the semiconductor device of the present invention combines a semiconductor device and a multilayer capacitor, and thus this multilayer capacitor functions to compensate the voltage drop that occurs during a change in the load, and a semiconductor device having a build-in voltage drop compensation function can be realized.

In addition, solder balls connected to the terminal pads of the semiconductor device are inserted inside the holes provided in the first dielectric part, the second dielectric part, and the third dielectric part, and these solder balls and the dielectric parts are electrically connected.

With this type of structure, the solder balls electrically connect the terminal pads of the semiconductor device and the terminal pads of the board, and at the same time, function to connect electrode layers together. Therefore, the semiconductor device of the present invention having a build-in decoupling capacitor can be mounted on a board by the same method as a typical BGA or CSP type semiconductor device.

The electric circuit board of the present invention has at least a semiconductor device and a three lead multilayer capacitor mounted on its substrate, and the three lead multilayer capacitor can function as a decoupling capacitor that compensates a voltage drop that occurs during a change in the load in the semiconductor device.

Conventionally, two lead multilayer ceramic capacitors have been widely used for decoupling capacitors that compensate momentary effects of a power source voltage related to a change in the load of a semiconductor device. In contrast, in the electronic circuit board of the present invention, a three lead multilayer capacitor is used as a decoupling capacitor, and because the capacitor has the properties of a low self inductance and a high LC resonance frequency, it can be advantageously applied to recent semiconductor devicees having a high clock frequency, and can realize an electric circuit board having a high operational stability.

As a concrete structure of this three lead multilayer capacitor, a power source electrode layer provided in a dielectric part that acts as a capacitor chip and is electrically connected to the power source line on the board, a ground electrode layer arranged on both surface sides of the power source electrode layers via respective dielectric layers and electrically connected to a ground line on the board, and a terminal electrode provided on both sides surfaces of the capacitor chip and electrically connected to both ends of the power source electrode layers are provided. Alternately, one in which power source layers are provided and this power source electrodes are electrically connected to each other through via holes that pass through dielectric layers interposed therebetween can be used. The above is a conventional three lead multilayer capacitor, but the multilayer capacitor of the present invention can also be used.

In addition, as an embodiment of the board, a multilayer capacitor can be mounted on the surface of the side of the board on which the semiconductor device is mounted, or mounted on the side opposite to that on which the semiconductor device is mounted, or can be buried in the board.

In addition, the electronic circuit board of the present invention is characterized in a semiconductor device having the characteristics of the present invention, that is, a BGA or CSP semiconductor device and the like, being combined with the multilayer capacitor of the present invention, and the semiconductor device having a built-in power source voltage drop compensation function mounted on the board.

As an electric circuit board, this structure is most rational. That is, problems of conventional electric circuit boards that provide a decoupling capacitor can be solved all at once: mounting of the multilayer capacitor onto the board and reducing the inductance component of the wiring between the decoupling capacitor and the LSI. Thereby, an electric circuit board that is easily assembled and has superior operational stability can be realized.

### BRIEF DESCRIPTION OF THE DRAWINGS

FIGS. 1A, 1B, and 1C are drawings showing the structure of the chip multilayer ceramic capacitor (feed-through internal electrode layer 1) using the electric circuit board of the present invention, where 1A is a perspective drawing, 1B is a cross-sectional drawing along the line B-B in FIGS. 1A, and 1C is a cross-sectional drawing along the line C-C in FIG. 1A.

FIGS. 2A, 2B, and 2C are drawings showing the structure of the chip multilayer ceramic capacitor (feed-through internal electrode layer 1) using the electric circuit board of the present invention, where 2A is a perspective drawing, 2B is a cross-sectional drawing along the line B-B in FIG. 2A, and 2C is a cross-sectional drawing along the line C-C in FIG. 1A.

FIGS. 3A, 3B, 3C, and 3D are drawings showing the structure of the multilayer capacitor according to the first embodiment of the present invention, where FIG. 3A is a planar drawing, FIG. 3B is a cross-sectional drawing along line C-C in FIG. 3A, and FIG. 3C is a planar drawing of the feed-through internal electrode that is one essential structural component of the capacitor, and FIG. 3D is a planar drawing of the internal electrode.

FIGS. 4A, 4B, and 4C are similarly enlarged cross-sectional drawings of the vicinity of each hole of the multilayer capacitor.

FIG. 5 is a cross sectional drawing showing the structure of a (bare chip) semiconductor device according to the second embodiment of the present invention.

FIG. 6 is a cross-sectional drawing showing the structure of a (CSP) semiconductor device according to the third embodiment of the present invention.

FIGS. 7A and 7B are drawings showing the structure of the electric circuit board according to the fourth embodiment of the present invention, where FIG. 7A is a planar drawing viewed from the LSI side, and FIG. 7B is a cross-sectional drawing.

FIGS. 8A and 8B are drawings showing the structure of the electric circuit board according to the fifth embodiment of the present invention, where FIG. 8A is a planar drawing viewed from the LSI side, and FIG. 8B is a cross-sectional drawing.

FIG. 9 is a cross-sectional drawing showing the structure of the electric circuit board according to the sixth embodiment of the present invention.

FIGS. 10A, 10B, and 10C are drawings showing an example of a conventional multilayer ceramic capacitor, where FIG. 10A is a perspective view, FIG. 10B is a cross-sectional view along line B-B in FIG. 10A, and FIG. 10C is a cross-sectional drawing along line C-C in FIG. 10A.

FIGS. 11A and 11B are drawings for explaining the simulation of the power source voltage drop in the LSI in the electric circuit board of the present invention, where FIG. 11A is the equalizing circuit diagram used in the simulation, and FIG. 11B is a schematic diagram representing the change in the power source voltage that occurs during a sudden change in the current flowing through the LSI.

### DETAILED DESCRIPTION OF THE INVENTION

First Embodiment

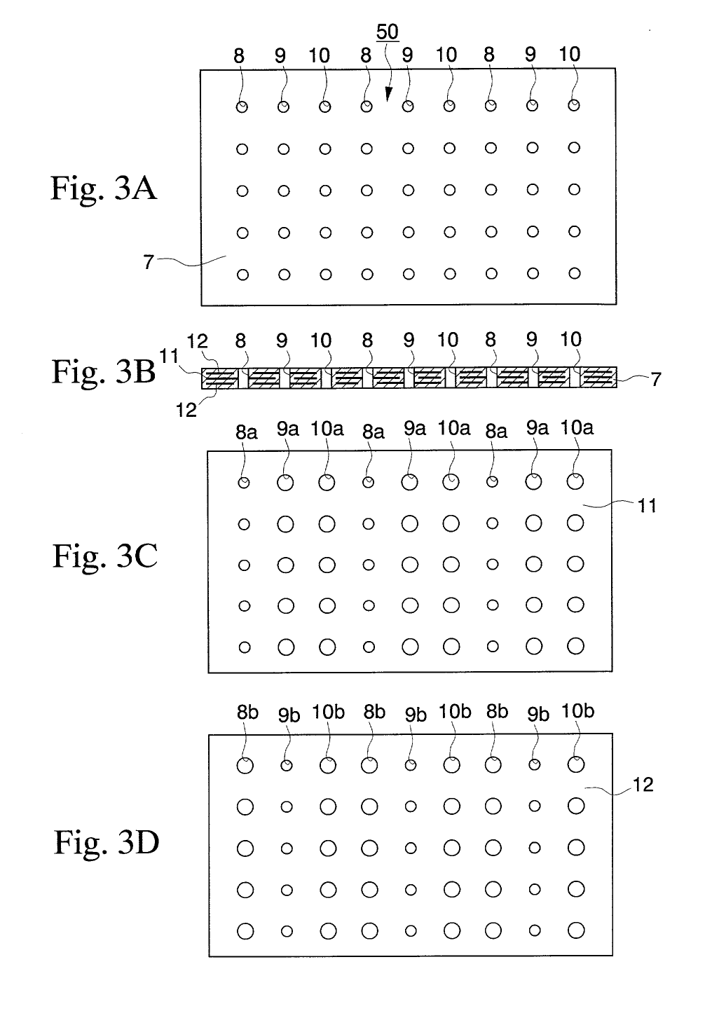

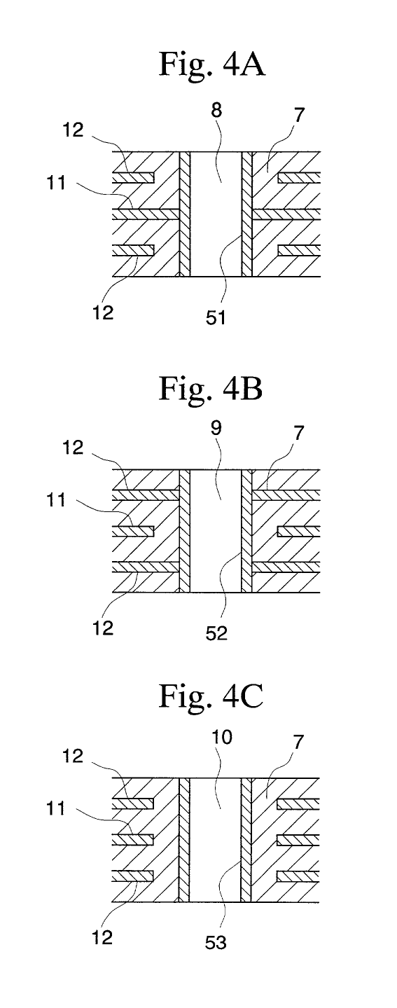

Below, the first embodiment of the present invention will be explained referring to FIG. 3 and FIG. 4.

This embodiment is an example of the multilayer capacitor of the present invention. FIG. 3A is a planar drawing of the multilayer capacitor of the present embodiment, FIG. 3B is a cross-sectional drawing along the line A-A in FIG. 3A, FIG. 3C is a planar drawing of the feed-through internal electrode that is an essential structural component of the multilayer capacitor, FIG. 3D is a planner drawing of the internal electrode, and FIGS. 4A, 4B, and 4C are enlarged cross-sectional drawings of the vicinity of each hole. Moreover, the multilayer capacitor shown as an example in the present embodiment is assumed to be incorporated into the LSI (semiconductor device) explained below in the second and third embodiments.

As shown in FIG. 3A and 3B, the multilayer capacitor in the present embodiment comprises a capacitor chip 50 in which sheet or plate shaped dielectric layers 7 (4 layers in this embodiment) and (3 layers in this embodiment) electrode layers 11 and 12 are alternately multilayer. In addition, holes 8, 9, and 10 arranged in a lattice (5 rows and 9 columns in the present invention) are provided so as to run from the upper surface to the lower surface of the capacitor chip 50. These holes 8, 9, and 10 are for connecting the terminal pad of the printed board and the LSI chip, and the position of each of the holes corresponds to the position of a terminal pad. The holes 8, 9, and 10 are arranged into a total of 9 rows, but the type of terminal pad connected to each individual row differ. Hole 8 is formed for connecting the VDD line (the power source line), hole 9 for connecting the GND line (the ground line), and hole 10 for connecting the SIG line (signal line).

In addition, among the three electrode layers, the middle layer is a sheet-shaped feed-through internal electrode 11 for connecting to the VDD line, and the layers positioned above and below are sheet-shaped internal electrodes 12 for connecting to the GND line via the dielectrics 7.

As shown in FIG. 3C, the feed-through internal electrode 11 connects only to the VDD line, and only a hole 8a has a small diameter so as not to connect to the GND line and the SIG line, the edge of the hole reaches to the inner surface of the hole 8. The hole 9a and hole 10a have larger diameters than the hole 8a, and the edge of the holes do not reach to the inner surface of a hole 9 and a hole 10. In contrast, the internal electrode 12 connects only to the GND line, and as shown in FIG. 3D, only the diameter of the holes 9b are small and the diameter of the holes 8b and 10b are large, so as not to connect to the VDD line and the SIG line.

As shown in FIG. 4A, a dielectric layer 51 (the first dielectric part) is provided that comprises metal and the like electrically connected to the feed-through internal electrode 11 on the inner surfaced of a hole 8. As shown in FIG. 4B, a dielectric layer 52 (the second dielectric part) is provided that is electrically connected to the internal electrodes 12 on the inner surface of the hole 9. As shown in FIG. 4C, a dielectric layer (the third dielectric layer) is provided that is not electrically connected either to the internal electrode 11 or the internal electrodes 12. In order to connect to the terminal pads of a printed board and an LSI chip, the inner surface of each of the holes 8, 9, and 10 must have at least the dielectric layer 51, 52, and 53 described above. Furthermore, the interior of the holes 8, 9, and 10 can be completely buried within the dielectrics. In addition, on the upper surface and the lower surface of the capacitor chip in which the plurality of holes 8, 9, and 10 have been opened, an electrode such as a terminal electrode is not provided, and the surface of the dielectrics 7 is exposed.

Moreover, this plate or sheet shaped capacitor chip 50 can take the form of a capacitor formed on a base film comprising an organic material or metal foil or a thin film capacitor.

The dielectrics 7 is formed by a perovskite compound having a high inductivity or a hybrid of a perovskite compound and an organic material. As a preferable perovskite compound, PbTiO₃ and BaTiO₃ can serve as the skeleton, and the average atomic value of the A site is made 2 by substituting Sr, Ca, La and the like for one part of the Pb or Ba site (A site), and the average atomic value of the B site can be made 5 by substituting Mg, W, Nb, Zr, Ni, Zn and the like for a part of the Ti (B site). The organic material forming the complex perovskite compound as a filler is not particularly limited, but because soldering is carried out on the connection between the substrate and the LSI, it would preferably have a heat-resistance of approximately 250° C.

The multilayer capacitor of the present embodiment is based on the capacitor chip 50 wherein a plurality of dielectric layers 7 and a plurality of electrode layers 11 and 12 are alternately multilayer, that is to say, form a thin film capacitor. Furthermore, because a feed-through internal electrode 11 and the internal electrodes 12 that surround it above and below are provided, this multilayer capacitor is equivalent to a three lead capacitor. Therefore, a capacitor having a sufficient capacitance, low self inductance, and a high LC resonance frequency can be realized.

Second Embodiment

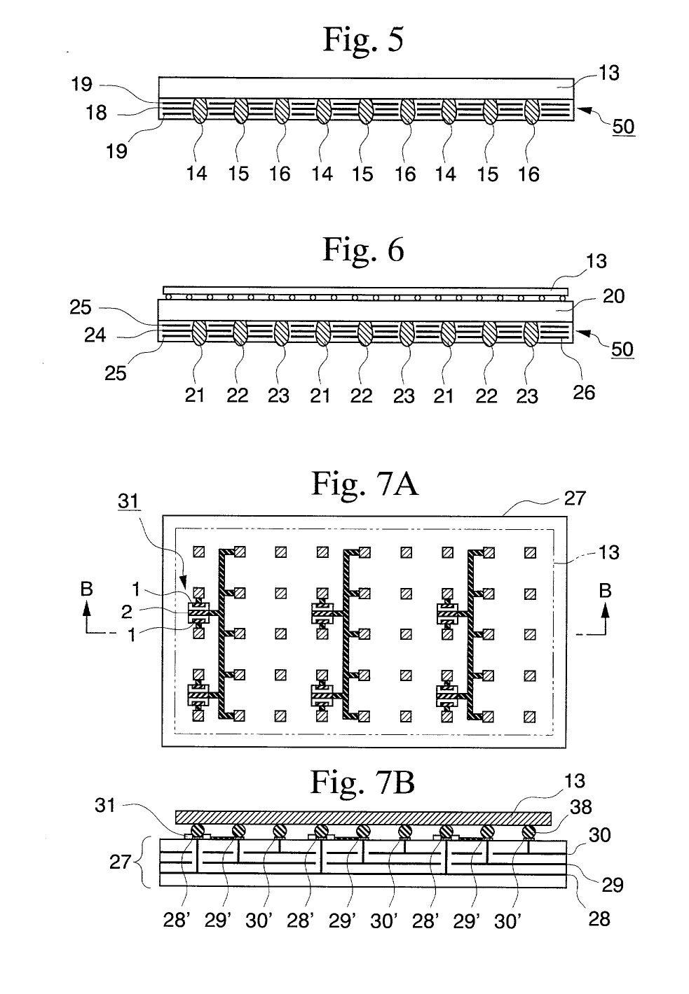

Below, the second embodiment of the present invention will be explained referring to FIG. 5.

This embodiment is an example of a semiconductor device of the present invention, and is an example of a structure in which the multilayer capacitor of the first embodiment is incorporated into the lower surface of a semiconductor device comprising a bare chip.

As shown in FIG. 5, in the semiconductor body apparatus of this embodiment, a plurality of terminal pads (not illustrated) are arranged in a lattice on the lower surface of an LSI bare chip 13, and on each of the terminal pads solder balls 14, 15, and 16 are respectively connected. In the figure, in sequence from the solder ball at the left end, there is a repeating arrangement of a solder ball 14 on the power source pad connected to the VDD line for the LSI, a solder ball 15 on the ground pad connected to the GND line, and a solder ball 16 on the signal pad connected to the SIG line. On the lower surface of the LSI bare chip 13, the capacitor chip 50 of the first embodiment is anchored. When anchoring the capacitor chip 50, after disposing the holes formed in the capacitor chip 50 so as to align with the solder holes 14, 15, and 16 of the LSI bare chip 13, the LSI bare chip 13 and the capacitor chip 50 are integrated by being passed through a reflow furnace.

With the multilayer capacitor anchored to the lower surface of the LSI bare chip 13, the solder balls 14, 15, and 16 are inserted inside the holes for the multilayer capacitor. In addition, only a feed-through internal electrode 18 is connected to a solder ball 14, only an internal electrode 19 is connected to a solder ball 15, and neither the feed-through internal electrode 18 nor the internal electrode 19 are connected to a solder hole 16. The electrical connection between the solder holes 14, 15, and 16 to the feed-through internal electrode 18 and the internal electrode 19 actually occurs via the dielectric layer explained in the first embodiment.

According to the semiconductor device of the present embodiment, because the LSI bare chip 13 is incorporated into the multilayer capacitor, this multilayer capacitor functions as a voltage drop compensator during a load change, and a semiconductor device having a built-in voltage drop compensation function can be realized.

In addition, because the solder balls 14, 15, and 15 connected to the terminal pads of the LSI bare ship 13 are inserted into the holes of the multilayer capacitor, and these solder balls 14, 15, and 16 and the dielectric part on the inner surface of the hole are electrically connected, if this semiconductor device is mounted, for example, on a printed board, the terminal pads of the LSI bare ship 13 and the terminal pads on the printed board are electrically connected by the solder holes 14, 15, and 16. Thereby, the semiconductor device of the present embodiment having a built-in decoupling capacitor can be mounted on a printed board by a method similar to that of a normal BGA or CSP type semiconductor device.

Thereby, the problems of conventional the electric circuit boards providing decoupling capacitors, such as mounting of the multilayer capacitor on a board and decreasing the inductance component of the wiring between the decoupling capacitor and the LSI, can be eliminated all together. By using the semiconductor device of the present embodiment, an electric circuit board that is easy to assemble and that has superior operational stability can be realized.

Third Embodiment

Below, the first embodiment of the present invention will be explained referring to FIG. 6.

The present embodiment is one example of the semiconductor device of the present invention, and has a structure wherein the multilayer capacitor of the first embodiment is incorporated into the lower surface of a semiconductor device comprising a CSP semiconductor device. FIG. 6 is a cross sectional drawing of the semiconductor device of the present embodiment.

As shown in FIG. 6, like the second embodiment, in the semiconductor device of the present embodiment a plurality of solder balls 21, 22, and 23 are arranged on the lower surface of the CSP 20 on which an LSI bare chip 13 has been mounted. In sequence from the solder ball at the left end, there is the repeating arrangement of a solder ball 21 10 connected to the VDD line for the LSI, a solder ball 22 connected to the GND line, and a solder ball 23 connected to the SIG line. In addition, the capacitor chip 50 of the first embodiment is anchored on the lower surface of the CSP 20.

The solder balls 21, 22, and 23 are inserted in the holes of the multilayer capacitor anchored to the lower surface of the CSP 20. In addition, only a feed-through internal electrode 24 is connected to a solder ball 21, only an internal electrode 25 is connected to a solder ball 22, and neither the feed-through internal electrode 24 nor the internal electrode 25 are connected to a solder ball 23. This structure of this part is completely identical to that of the second embodiment.

In the semiconductor device of the present embodiment as well, the same effects as those of the second embodiment can be attained: a semiconductor device having a built-in voltage drop compensation function can be realized, mounting on the board can be easily carried out, and the inductance component of the wiring between the decoupling capacitor and the LSI can be decreased.

Fourth Embodiment

Below, the fourth embodiment of the present invention will be explained referring to FIG. 7.

The present embodiment is one example of the electric circuit board of the present invention, and shows an example in which a multilayer capacitor is mounted on the surface of the side on which the LSI is mounted. FIG. 7A is a planar drawing of the electric circuit board of the present embodiment, and FIG. 7B is a cross-sectional drawing.

As shown in FIGS. 7A and 7B, in the electric circuit board of the present invention, the LSI (the external shape of which is shown by reference numeral 13) and the multilayer capacitor 31 are mounted on the upper surface on the same side of the printed circuit 27. The multilayer capacitor 31 of the present embodiment is a three terminal multilayer capacitor, and functions as a decoupling capacitor that compensates a voltage drop that occurs during a load change in the LSI.

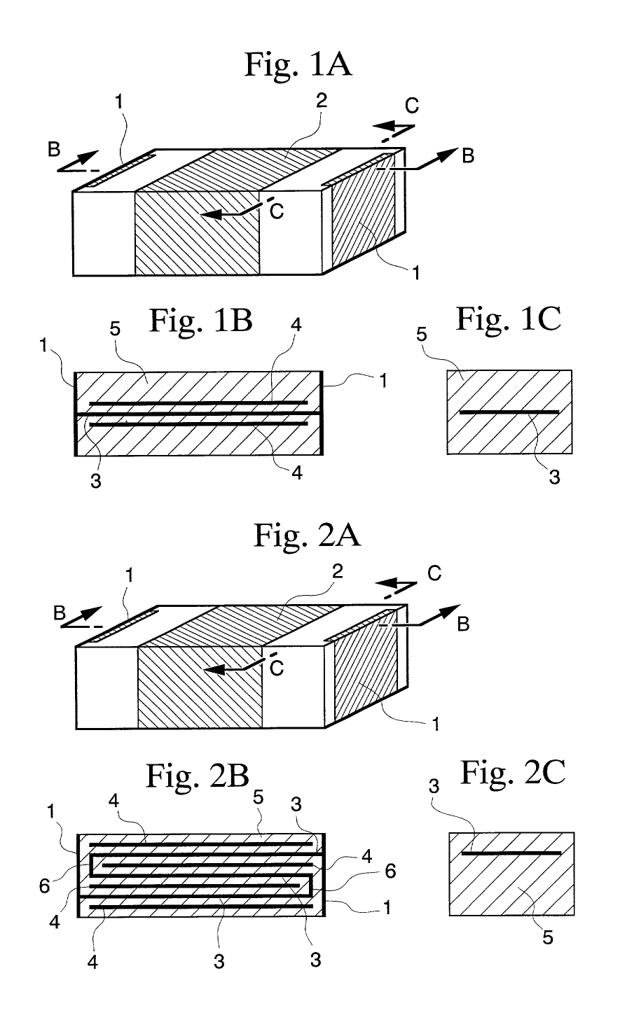

In the present embodiment, a multilayer capacitor such as that shown in FIG. 1 can be used. Specifically, the multilayer capacitor shown in FIG. 1 has a structure wherein the feed-through internal electrode (the electrode layer for the power source) connected to the VDD line is provided in the dielectrics 5, and the internal electrode 4 (the electrode layer for the ground) of the two layers connected to the GND line are provided separated from the feed-through internal electrode 3 on both surface sides of the feed-through internal terminal 3. In addition, both ends of the feed-through internal electrode 3 are connected to the terminal electrode I on the end surfaces of the capacitor chip, and each of the internal electrodes 4 is connected to the terminal electrode 2 provided on the side surfaces and the upper and lower surfaces of the capacitor chip.

Alternatively, a multilayer capacitor such as that shown in FIG. 2 can be used. Specifically, in the multilayer capacitor shown in FIG. 2, a plurality (3 layers in the present embodiment) of feed-through internal electrodes 3 connected to the VDD line is provided in the dielectrics 5, and a plurality (4 layers in the present embodiment) of internal electrodes 4 connected to the GND is provided so as to surround each of the feed-through electrodes. In addition, at the ends of a feed-through internal electrode 3, via holes that run though the dielectrics 5 that are interposed therebetween are formed. The three layers of the feed-through internal electrodes 3 are electrically connected to each other by a via electrode 6 in the via hole that is not exposed to the outside. In addition, like the capacitor shown in FIG. 1, both ends of the feed-through internal electrodes 3 are connected to each of the terminal electrodes 1, and each of the internal electrodes 4 is respectively connected to the terminal electrodes 2.

The structure of the multilayer capacitor is as shown in FIGS. 7A and 7B. Specifically, in order to mount the LSI such as the CSP or bare chip and the like on the surface of the printed board 27, the pitch of the pads 28′, 29′, and 30′ on the printed board 27 conforms to the pitch of the solder bumps 38 (pad) of the LSI. In addition, the printed board 27 of the present embodiment is what is termed a multi-layer print wiring board, in which the VDD line 28, the GND line 29, and the SIG line 30 are multilayer in the board in sequence from the bottom. In addition, on the surface of the printed board 27, pads 28′ connected to the VDD line 28, pads 28′ connected to the GND line, and pads 30′ connected to the SIG line are disposed in a matrix shape.

In addition, the multilayer capacitor shown in FIG. 1 or FIG. 2 is mounted on the printed board 27 surface using solder such that the terminal electrodes 1 on both ends of the capacitor chip connected to the feed-through internal electrode 3 is connected to the VDD line 28, and the electrodes 2 on both side surfaces of the capacitor are connected to the pad 29′ that is connected to the GND line via wiring 32 made of copper and the like. The multilayer capacitor 3 Imust be thin in order that this capacitor 31 be positioned between the CSP or bare chip and the printed board 27. Specifically, this must be equal to or less than approximately 0.33 mm.

In the electric circuit board of the present embodiment, the three lead multilayer capacitor 31 is used as a decoupling capacitor, and this multilayer capacitor 31 has the properties of low self inductance and a high LC resonance frequency. Thus, it can be advantageously applied to recent LSI having a high clock frequency, and can realize an electric circuit board having a high operational stability.

Fifth Embodiment

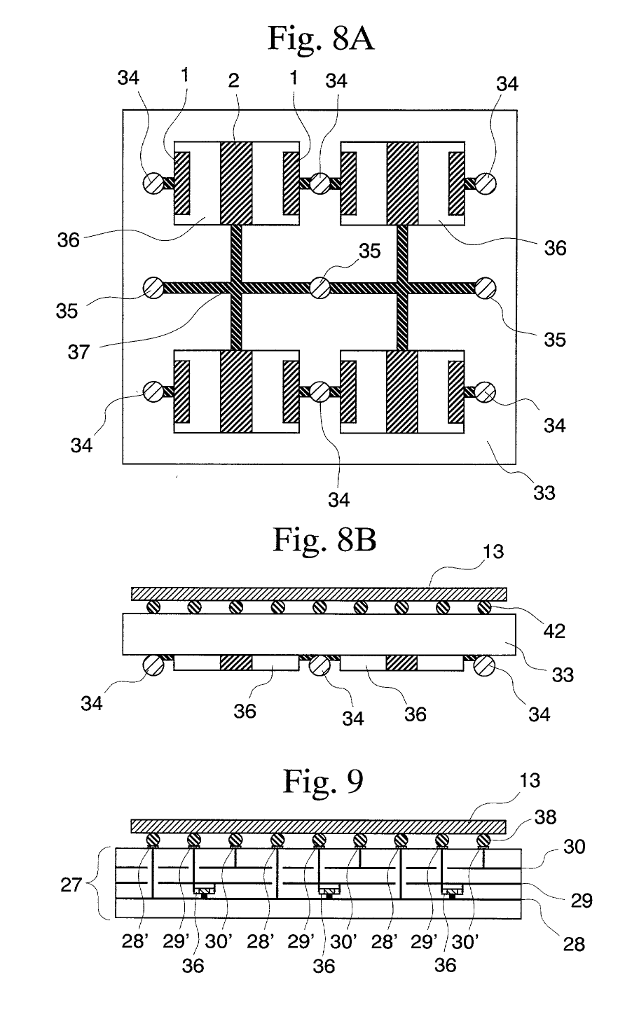

Below, the fifth embodiment of the present invention will be explained referring to FIG. 8.

The present embodiment is one example of an electric circuit board of the present invention, and shows an example of a multilayer capacitor that is mounted on the side opposite to that on which the LSI is mounted. FIG. 8A is a drawing in which the electric circuit board of the present embodiment is viewed from below, and FIG. 8B is a cross-sectional view of the same.

As shown in FIG. 8A and 8B, in the electric circuit board of the present invention, the LSI 13 and the multilayer capacitor 36 are mounted on opposite surfaces of the printed board 33. The multilayer capacitor 36 in the present embodiment is a three lead multilayer capacitor, and functions as a decoupling capacitor that compensates the voltage drop that occurs during a load change in the LSI.

Like the fourth embodiment, the multilayer capacitors shown in FIG. 1 and FIG. 2 can be used in the present embodiment as well. In addition, the printed board provides corresponding pads on both the upper surface and lower surface. In addition, on the lower surface of the printed board 33, the multilayer capacitor 36 is mounted using solder and the like such that the feed-through internal electrode 3 is connected to the pad 34 connected to the VDD line, and the terminal electrode 3 connected to the internal electrode 4 is connected to the pad 35 connected to the GND line via the wiring 37.

In the electric circuit board of the present invention as well, effects similar to those of the fourth embodiment can be attained: advantageous application to an LSI having a high clock frequency and realization of an electric circuit board having a high operational stability.

Sixth embodiment

Below, the sixth embodiment of the present invention will be explained referring to FIG. 9.

The present embodiment is one example of the electric circuit board of the present invention, and shows an example in which the multilayer capacitor is buried inside the substrate. FIG. 9 is a cross-sectional diagram of the electric circuit board of the present invention.

As shown in FIG. 9, in the electric circuit board of the present embodiment, the LSI 13 is mounted on the printed board 27, and the multilayer capacitor 36 is buried inside the printed board 27. The multilayer capacitor 36 of the present embodiment is also a three lead multilayer capacitor, and the terminal electrode seen from the front in FIG. 9 is a feed-through electrode and is connected to the VDD line 28 inside the printed board 27. In contrast, there is a terminal electrode corresponding to the ground electrode on the side surface of the multilayer capacitor in FIG. 9, and this is connected to the GND line 29 inside the printed board 27. The three lead multilayer capacitor buried in the printed board 27 shown in FIG. 9 functions as a decoupling capacitor that compensates a voltage drop that occurs during a load change in the LSI.

Moreover, the technical scope of the present invention is not limited to the above-described embodiments, and modifications may be made that do not depart from the spirit of the invention. For example, in the second and third embodiments shown in FIG. 5 and FIG. 6, an example in which the multilayer capacitor of the first embodiment is joined to the lower surface of the LSI, but if there is sufficient space to mount the capacitor shown in FIG. 1 and FIG. 2 in the space between the solder balls on the lower surface of the LSI, the capacitors shown in FIG. 1 and FIG. 2 can be used. In addition, in the first embodiment, an example of a multilayer capacitor was shown that provides a first electrode layer connected to the VDD line and a second electrode layer connected above and below to the GND line, but more electrode layers can be provided by alternately disposing electrode layers connected to the VDD line and electrode layers connected to the GND line.

### EXAMPLES

### Example 1

First, the fabrication method and mounting method of the capacitor of the first example is shown.

The dielectric powder uses barium titanate as a base. The powder has an induction rate of 2500 at room temperature and satisfies X7R properties. A solvent and a binder are added to the inducting powder by a doctor blade method, and a green sheet is made from the mixed slurry. The thickness of the green sheet is 30 μm. The dielectric paste that forms the feed-through electrode and the ground electrode in the green sheet is shaped using the printing screen method. Because the baking temperature of the dielectric is equal to or greater than 1300° C., a platinum paste is used in the indicting paste.

Next, the green sheet on which the electrodes are printed is cut into predetermined shapes, and after lamination and crimped, each chip is diced. After these chips have the binder removed and are baked at a predetermined temperature profile, the terminal electrode shown in FIG. 2 is formed by printing the silver paste, and thereby the three lead multilayer ceramic capacitor is fabricated. The structure of this capacitor is shown in FIG. 2. The dimensions of this three lead multilayer ceramic capacitor conform to the standards for normal SMD (surface mountable devices), and are L 2.0 mm×W 1.2 mm×T 1.0 mm. The diameter of the via (after baking) is φ 0.1 mm, and connects the feed-through internal electrode above and below. There are five layers of feed-through internal electrodes and six layers of ground electrodes. The static capacitance between the feed-through electrode and the ground is measured using the impedance analyzer HP4194A (Agirent Manufacturing Co. Ltd.), and the capacitance assuming a serial equalizing circuit was found to be 11.2 nF at 1 MHz.

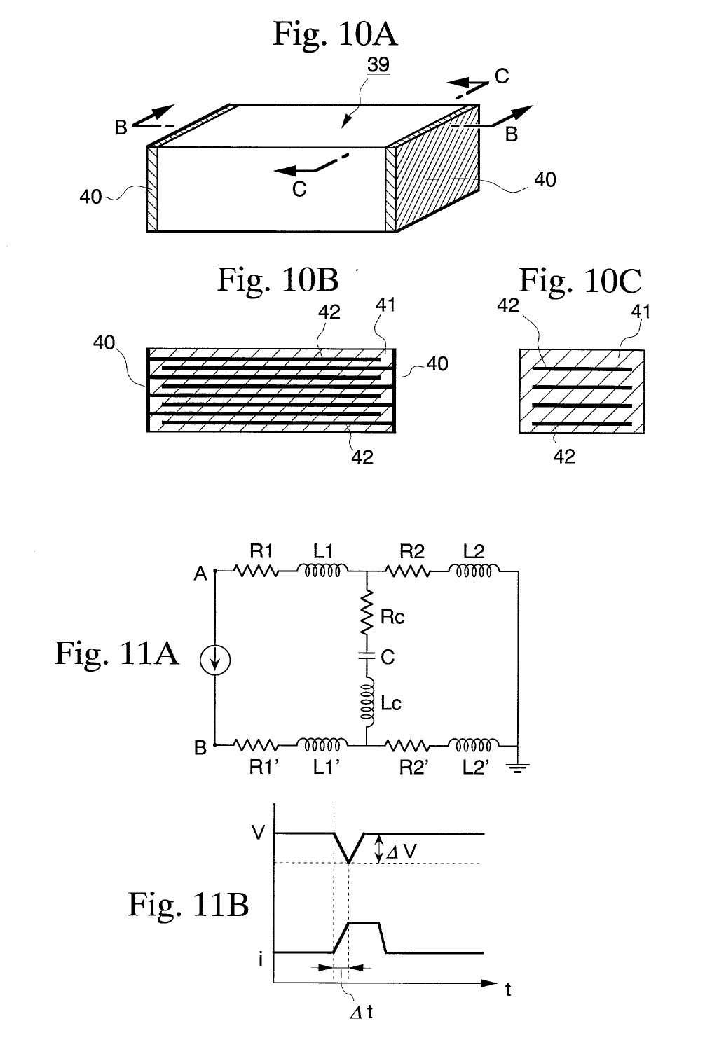

In order to compare the properties of the capacitor, a conventional ceramic capacitor having the structure in FIG. 10, and having the same shape (C12) and the same capacitance (10 nF) was prepared. In comparison with the frequency properties of the impedance of the above-described three lead ceramic capacitor using a high frequency impendence analyzer HP4291A, the LC resonance frequency of the impedance in the two lead multilayer ceramic capacitor was 60 MHz, whereas the LC resonance frequency in the three lead multilayer ceramic capacitor was 79 MHz. When the self inductance L is found using equation 2, where f is the LC resonance frequency, it is approximately 0.7 nH in the two lead multilayer capacitor, whereas it is approximately 0.4 nH in the three lead multilayer ceramic capacitor.

As shown in FIG. 8, the multi-lead multilayer ceramic capacitor is mounted on the bottom surface of the printed board. The shape of the printed board is 100 mm by 100 mm, and the area for mounting this capacitor thereon is 20 mm×20 mm. The above-described multilayer ceramic capacitor is mounted as a decoupling capacitor that compensates a power source voltage drop that occurs during a load change. On the remaining area of the printed board, the electronic circuit board is fabricated by mounting other components such as a high capacitance capacitor having a capacitance of about 1 μF, in addition to inductors, resistors and the like.

The drop ΔV in the power source voltage of the LCR that occurs during a sudden change in the load using a decoupling capacitor was found by carrying out a simulation using the equalizing circuit diagram such as that shown in FIG. 11A on the electric circuit board. Lc, C, and Rc respectively denote the equivalent series inductance, the electrostatic capacitance, and equivalent series resistance of the decoupling capacitor. R1 and R1′ represent the resistance of the wires present in the wiring between the decoupling capacitor and the LSI. R2 and R2′ denote the resistance of the wires between the decoupling capacitor and the power source. L2 and L2′ denote the wiring inductance. Here, the case in which a pulse having a clock frequency of 500 MHz is applied to the LSI is assumed. The rise time here is empirically the pulse cycle 2 ns (a/500 MHz)/4=0.5 ns.

FIG. 11B will be explained. Under normal conditions, the current i is supplied as a constant current from the power source. At this time, in the decoupling capacitor, the load becomes fully accumulated. Here, when the current suddenly flows due to a rapid change with respect to the constant condition of the load in the LSI, the load corresponding to the increased current is supplied from the decoupling capacitor. At this time, the voltage drop ΔV in the LSI is represented by equation 1.

Here, the equivalent series resistance Rc for both the two lead decoupling capacitor and the three lead decoupling capacitor is set to Rc=0.1 Ω. In addition, AV was found using the values R1=R′=0.0025 Ω, Rc=0.1 Ω, L1=L1′=1 nH (corresponding to about 1 mm), Lc of the two lead multilayer ceramic capacitor =0.7 nH, and Lc of the three lead multilayer ceramic capacitor=0.4 nH. The current i(t) during the rise of the pulse is denoted by equation 4 using the value of current Δi =0.3A generated from a general LSI having a clock frequency of 500 MHz.

From equation 1 to equation 4, using the three lead multilayer ceramic capacitor such as that shown in FIG. 2 as the decoupling capacitor for compensating a voltage drop that occurs during a sudden load change in the LSI, the ΔV1 in the electric circuit board mounted as shown in FIG. 8 and ΔVr in the electric circuit board having mounted as shown in FIG. 8 having the same layout as the two lead multilayer ceramic capacitor such as that shown in FIG. 10 are calculated as follows. Here, because the voltage drop that occurs during the rise of the pulse is largest, the time t=0.5 ns.

$$\begin{matrix}Δ V1 = R \times 0.6 \times {10}^{9} \times t + L \times 0.6 \times {10}^{9} \\ ≅ 0.0315 + 1.44 \\ = 1.4715 V\end{matrix}$$

$$\begin{matrix}Δ Vr = r \times 0.6 \times {10}^{9} \times t + L \times 0.6 \times {10}^{9} \\ ≅ 0.0315 + 1.62 \\ = 1.6515 V\end{matrix}$$

Therefore, we can understand that the voltage change ΔV that occurs during a sudden change in the load of the LSI is smaller in the semiconductor device such as that shown in FIG. 8 on which the three lead ceramic capacitor shown in FIG. 2 is mounted.

In this embodiment, the length of the wiring between the LSI and the decoupling capacitor is 1 mm. In this case, following the above calculation, the voltage change has improved by 11%. However, the percentage of improvement in the voltage change decreases as the length of the wiring between the LSI and the decoupling capacitor becomes longer.

Here, when the length of the wiring between the LSI and the decoupling capacitor is X mm, the voltage drop ΔVx in the case of using the three lead ceramic decoupling capacitor and the voltage drop Δrx in the case of using a ceramic capacitor having a conventional structure as a decoupling capacitor are respectively as follows:

$$\begin{matrix}Λ Vx = R \times 0.6 \times {10}^{9} + 0.5 ns + L \times 0.6 \times {10}^{9} \\ = 0.03 + ( 2 X + 0.4 nH ) \times 0.6 \times {10}^{9}\end{matrix}$$

$$\begin{matrix}Λ Vrx = R0 .6 \times {10}^{9} + 0.5 ns + L \times 10 \times {10}^{9} \\ = 0.03 + ( 2 X + 0.7 nH ) 0.6 \times {10}^{9}\end{matrix}$$

Here, the resistance due to the wiring between the LSI and the decoupling capacitor is extremely small compared to the resistance of the capacitor, and thus has been ignored.

Considering that the tolerance error of the power source voltage in the LSI is 5%, in the case that

(ΔVrx−ΔVx)/ΔVrx<5%

the improvement of the inductance due to the capacitor does not effect the improvement of the change in the power source voltage in the LSI. Solving the above equation,

X>2.625.

Therefore, in the case that the length of the wiring between the LSI and the decoupling capacitor exceeds 2.625 mm, we can say that the improvement in the power source voltage in the LSI due to the capacitor ceases to be effective.

### Example 2

Next, as a decoupling capacitor for complementing a drop in the power source voltage that occurs during a sudden change in the load in the LSI, consider the case of using the sheet shaped multilayer capacitor such as that shown in FIG. 3. The following is the fabrication process for the same.

A green sheet having a thickness of 55 μm was fabricated using the doctor blade method using the same dielectric powder as that in example 1. Next, after cutting the green sheet into a predetermined shape for each carrier film, feed-through electrodes 11 and internal electrodes 12 are formed using a screen printing method on the green sheets. In a sheet that forms a feed-through internal electrode 11, at positions corresponding to the holes 9 and 10, areas of φ 250 μm are provided on which the electrode ink is not applied. Similarly, in a sheet that forms an internal electrode 12, at positions corresponding to holes 8 and 10, areas of φ 250 μm are provided on which the electrode ink is not applied. Next, holes 8 to 10 are formed in each sheet that forms a feed-through internal electrode 11 and an internal electrode 12 using a laser processing machine.

On the sheet on which the feed-through internal electrodes 11 are formed, formation of the hole 8 in the areas where the electrode ink has been applied and formation of the holes 9 and 10 in the areas where the electrode ink has not been applied is confirmed. Similarly, on the sheet on which an internal electrode 12 is formed, formation of the hole 9 on areas where the electrode ink has been applied and formation of holes 8 and 10 on areas where the electrode ink has not been applied is confirmed.

Next, the burying of vias in sequence of the internal electrode 12, the feed-through electrode 11, and the internal electrode 12 is carried out. In order to provide sufficient strength for handling, after laminating several layers of sheets on which the holes 8 to 10 have been formed and the electrode ink has not been printed, the multilayer body is fabricated by heat attachment by a isostatic press. After cutting individual pieces of about 20 mm squares from the multilayer body, by carrying out binder removal and baking, the capacitor shown in FIG. 3 is fabricated. Among the three electrode layers of this capacitor, the center feed-through internal electrode layer is connected to the power source line, and the two internal electrode layers that surround the feed-through internal electrode layer are connected to the ground line, thereby becoming equivalent to the three lead capacitor shown in FIG. 1 and FIG. 2.

A probe is applied to the terminal connecting to a power source line and ground line pair adjacent to the fabricated capacitor, and when the frequency property of the impedance was measured, an LC resonance frequency of approximately 100 MHz was observed. An equivalent series inductance of approximately 10 pH was found from the LC resonance frequency by the same method as that descried in example 1. In a comparative example (25 commercially available 0.01 μF multilayer ceramic capacitors), the equivalent series inductance of one multilayer ceramic capacitor was about 0.7 nH, which would yield an inductance of 0.7 nH/25=28 pH in the case that 25 multilayer ceramic capacitors are connected in parallel between the power source and the ground of the LSI.

Therefore, the inductance of the decoupling capacitor connected between the power source and the ground of the LSI is 10 pH for this example, and 28 pH for the comparative example. Thus, the decoupling capacitor of the present invention can realize a low inductance. Assuming a capacitor equivalent series circuit was used, a capacitance at 1 MHz was calculated so that 0.25 μF so as to match the comparative example.

The fabricated capacitor is connected on the CSP side so as to be positioned between the CSP and the board, as shown in FIG. 6. The connection between the capacitor and the CSP uses a flip chip bonder such that the position of the holes and the bumps on the CSP side conform to each other. Subsequently, several solder balls having a diameter of 120 μm are inserted at one time into the holes in the capacitor, and a semiconductor device having the shape of a capacitor type CSP such as that shown in FIG. 6 is fabricated. Similar to comparative example 1, a drop in the power source voltage that occurs during a change in the load in the LSI was found using the equalizing circuit in FIG. 11A. Clearly, in the semiconductor device in the present example, the inductance of the decoupling capacitor provided between the power source and the ground of the LSI is small, and thus the drop of the power source voltage in the LSI is small.

As explained above in detail, because the multilayer capacitor of the present invention is a three lead capacitor, a capacitor having a sufficient capacitance, a low self inductance, and a high LC resonance frequency can be realized. In addition, the semiconductor device of the present invention combines a semiconductor device of a bare chip, BGA, or CSP semiconductor device and the like with the multilayer capacitor of the present invention, and thus this multilayer capacitor functions to compensate a voltage drop that occurs during a load change in the semiconductor device, and a semiconductor device having a built-in voltage drop compensation function can be realized. In addition, the semiconductor device of the present invention having the built-in decoupling capacitor can be easily realized on a board by a method similar to a typical BGA or CSP semiconductor device. Furthermore, according to the electronic circuit board of the present invention, an electronic circuit board can be realized that can be advantageously applied to the recent semiconductors having a high clock frequency and having a high operational stability. In addition, according to the semiconductor with the characteristics of the present invention, problems with the conventional electric circuit board can be resolved. These problems include mounting of the multilayer capacitor onto the board and reducing the inductance component of the wiring between the decoupling capacitor and the LSI.

What is claimed is:

1. A multilayer capacitor that provides a plurality of holes that run through a plurality of dielectric layers and a plurality of electrode layers on a capacitor chip comprising alternating laminations of said plurality of dielectric layers and said plurality of electrode layers, and providing a first dielectric part comprising a dielectrics electrically connected to a portion of the electrode layers among said plurality of electrode layers on the inner surface of the holes of one portion among the plurality of holes, and at the same time, provides a second dielectric part comprising a dielectrics electrically connected to the electrode layer adjacent to the electrode layer electrically connected to said first dielectric part among said plurality of electrode layers on the inner surface of at least a portion of the holes among the remaining holes, and said dielectric layer of the main surface of said capacitor chip having said plurality of hole openings is exposed.

2. A multilayer capacitor according to claim 1 providing a third dielectric part comprising a dielectrics is provided on the inner surface of the holes that, among said plurality of holes, remain after excluding the holes provided by said first dielectric part and the holes provided by said second dielectric part, wherein there is no electrical connection between said third dielectric part and said plurality of electrode layers.

3. A multilayer capacitor according to claim 1 wherein a dielectrics can be buried inside a hole provided in said first dielectric part, said second dielectric part, and said third dielectric part.

4. A multilayer capacitor according to claim 1, wherein a compound having a perovskite structure is preferably used as a material for said dielectric layer.

5. A multilayer capacitor according to claim 1 wherein a hybrid of a compound having a perovskite structure and an organic material is preferably used as materials for said dielectric layer.

6. A semiconductor device wherein said multilayer capacitor according to claim 1 is fixed to the surface side on which a plurality of terminal pads of the semiconductor device are provided, the power source pads among said plurality of terminal pads and said first dielectric part are electrically connected, and the ground pad and said second dielectric part are electrically connected.

7. A semiconductor device wherein said multilayer capacitor according to claim 2 is fixed to the surface side on which the plurality of terminal pads of the semiconductor device are provided, the power source pads among said plurality of terminal pads and said first dielectric part are electrically connected, and the ground pad and said third dielectric part are electrically connected.

8. A semiconductor device according to claim 6 wherein said semiconductor device comprises a bare chip.

9. A semiconductor device according to claim 6 wherein said semiconductor device comprises a semiconductor package.

10. A semiconductor device according to any of claim 6 wherein solder balls connected to said terminal pads of the semiconductor device are inserted inside the holes provided in said first dielectric part, said second dielectric part, and said third dielectric part, and these solder balls and said dielectric parts are electrically connected.

11. An electric circuit board wherein at least a semiconductor device and a three lead multilayer capacitor are mounted on the board, and said three lead multilayer capacitor can function as a decoupling capacitor that compensates the voltage drop that occurs during a change in the load in said semiconductor device.

12. An electric circuit board according to claim 11 wherein said three lead multilayer capacitor comprises a power source electrode layer provided in a dielectric part that acts as a capacitor chip and is electrically connected to the power source line on the board, a ground electrode layer arranged on both surface sides of said power source electrode layers via respective dielectric layers and electrically connected to a ground line on the board, and a terminal electrode provided on both sides surfaces of said capacitor chip and electrically connected to both ends of said power source electrode layers are provided.

13. An electric circuit board according to claim 12 wherein a plurality of said power source layers are provided, and this plurality of power source electrodes are electrically connected to each other through a via holes that pass through dielectric layers interposed therebetween.

14. An electric circuit board wherein at least a semiconductor device and said multilayer capacitor according to claims 1 are mounted on the board, and said multilayer capacitor can function as a decoupling capacitor that compensated a voltage drop that occurs during a change in the load of said semiconductor device.

15. An electric circuit board according to claim 11 wherein said three lead multilayer or said multilayer capacitor is mounted on the surface on the side of said board on which said semiconductor device is mounted.

16. An electric circuit board according to claim 11 wherein said three lead multilayer capacitor or said multilayer capacitor is mounted on the surface opposite to the surface of said board on which said semiconductor device is mounted.

17. An electric circuit board according to claim 11 wherein said three lead multilayer capacitor or said multilayer capacitor is buried inside said board.

18. An electric circuit board wherein at least the semiconductor device according to claim 6 is mounted on said board.
